(19) United States
(12) Patent Application Publication
(10) Pub. No.: US 2026/0120781 A1
(43) Pub. Date: Apr. 30, 2026

(54) METHOD OF SETTING INITIAL ERASE VOLTAGE

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/292,947

(22) Filed: Aug. 7, 2025

(30) Foreign Application Priority Data
Oct. 24, 2024 (TW) 113140634

(51) Int. Cl. G11C 16/34; G11C 16/14; G11C 16/30

(52) U.S. Cl. CPC G11C 16/3445; G11C 16/14; G11C 16/30

(57) ABSTRACT

Provided is a method of setting an initial erase voltage that includes: a pre-programming operation is performed to first target memory cells; an erase operation is performed to the first target memory cells by setting an erase voltage and using the erase voltage; an erase verification operation is performed to the first target memory cells by using multiple verification voltages; and whether to set the erase voltage as the initial erase voltage is determined based on an erase verification result. The multiple verification voltages include a first verification voltage and a second verification voltage. The second verification voltage is greater than the first verification voltage. Steps of performing the erase verification operation to the first target memory cells by using the multiple verification voltages include: the erase verification operation is performed to the first target memory cells by sequentially using the first verification voltage and the second verification voltage.

### CROSS-REFERENCE TO RELATED APPLICATION

This application claims the priority benefit of Taiwan application serial no. 113140634, filed on Oct. 24, 2024. The entirety of the above-mentioned patent application is hereby incorporated by reference herein and made a part of this specification.

### BACKGROUND

### Technical Field

The disclosure relates to a method of setting a voltage, and in particular to a method of setting an initial erase voltage.

### Description of Related Art

An erase time of a flash memory is an important factor related to the test cost and the product application. For a NOR flash memory product with a tunnel oxide structure, a charge trap may be generated in the tunnel oxide; therefore, the erase time may be longer during cycling operations.

In the conventional technology, in order to shorten the erase time, when an erase operation is performed, an erase pulse is first sent, and then an erase verification is performed to determine whether target memory cells pass the verification. If the target memory cells fail to pass the erase verification, erase pulses may be continuously sent. Repeatedly, an erase voltage may be increased after several erase pulses to speed up erasing.

In the foregoing erase operation, an initial erase voltage needs to be set. Generally, the initial erase voltage of a wafer or a batch of samples is set to be the same. However, there are die-to-die differences in the wafer process, and the erase time may increase with cycling operations. Therefore, the same initial erase voltage might not be appropriate for all wafers or samples.

### SUMMARY

The disclosure provides a method of setting an initial erase voltage, which can set different initial erase voltages for memory dies to reduce an erase time.

The embodiment of the disclosure provides the method for setting the initial erase voltage. The method includes: a pre-programming operation is performed to first target memory cells; an erase operation is performed to the first target memory cells by setting an erase voltage and using the erase voltage; an erase verification operation is performed to the first target memory cells by using multiple verification voltages; and whether to set the erase voltage as the initial erase voltage is determined based on an erase verification result. The multiple verification voltages include a first verification voltage and a second verification voltage. The second verification voltage is greater than the first verification voltage. Steps of performing the erase verification operation to the first target memory cells by using the multiple verification voltages include: the erase verification operation is performed to the first target memory cells by sequentially using the first verification voltage and the second verification voltage. Steps of determining whether to set the erase voltage as the initial erase voltage based on the erase verification result include: the erase voltage is set as the initial erase voltage when a quantity of first target memory cells that do not pass a verification of the first verification voltage and pass a verification of the second verification voltage is greater than a reference quantity.

### BRIEF DESCRIPTION OF THE DRAWINGS

FIG. 1 is a schematic block diagram of a memory storage device according to an embodiment of the disclosure.

FIG. 2 is a schematic diagram of a distribution of threshold voltages of memory cells according to an embodiment of the disclosure.

FIG. 3 is a flow chart of a method of setting an initial erase voltage according to an embodiment of the disclosure.

FIG. 4 is a flow chart of a method of setting an initial erase voltage according to another embodiment of the disclosure.

FIG. 5 is a schematic block diagram of a memory storage device according to another embodiment of the disclosure.

FIG. 6 is a flow chart of a method of setting an initial erase voltage according to another embodiment of the disclosure.

FIG. 7 is a flow chart of a method of setting an initial erase voltage according to another embodiment of the disclosure.

### DESCRIPTION OF THE EMBODIMENTS

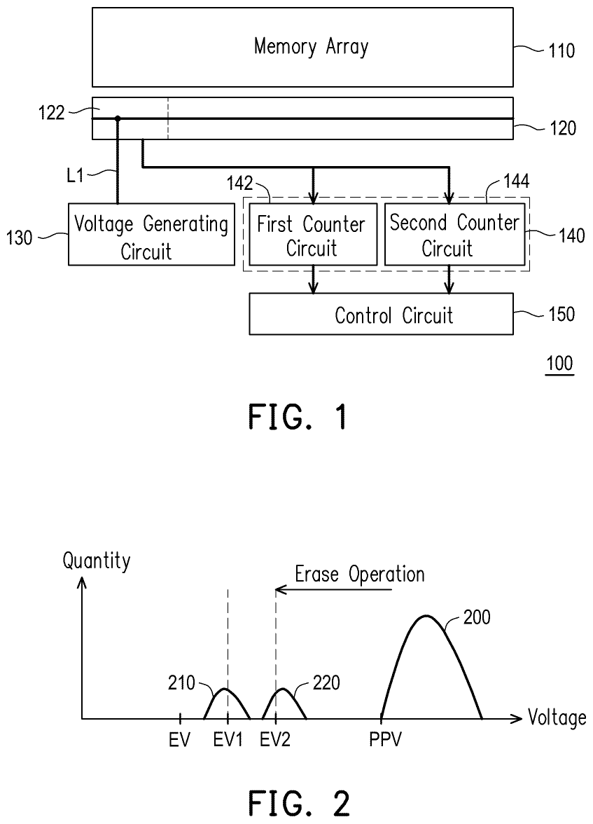

Refer to FIG. 1. A memory storage device 100 includes a memory array 110, a sense amplifier circuit 120, a voltage generating circuit 130, a counter circuit 140 and a control circuit 150. The memory array 110 includes multiple memory cells. The memory storage device 100 is, for example, a NOR flash memory, but the disclosure does not limit the type of the memory storage device 100.

The control circuit 150 is configured to perform a pre-programming operation, an erase operation or an erase verification operation to the memory array 110. For example, the control circuit 150 may be configured to set an initial erase voltage of the erase operation and set a verification voltage for the erase verification operation. The control circuit 150 is configured to perform the erase operation of a block or a sector to the memory array 110 based on an erase command. Before the erase operation is performed, the control circuit 150 may first perform the pre-programming operation to the block or the sector that has been selected and set the initial erase voltage of the erase operation. Next, the erase operation is performed to the block or the sector that has been selected.

In an embodiment, the control circuit 150 may be a digital logic circuit that is designed, for example, through hardware description language (HDL) or any other digital circuit design method well known to those skilled in the art, and a hardware circuit that is implemented through a method of field programmable gate array (FPGA), complex programmable logic device (CPLD) or application-specific integrated circuit (ASIC). Alternatively, the control circuit 150 may also be a processor or a controller with computing capabilities.

In addition, hardware structures of the memory array 110, the sense amplifier circuit 120, the voltage generating circuit 130 and the counter circuit 140 can be sufficiently taught, suggested and implemented by common knowledge in the technical field.

The following describes how the control circuit 150 sets the initial erase voltage for the erase operation. Refer to FIGS. 1 to 3. In FIG. 2, the horizontal axis is the threshold voltage of a memory cell, the vertical axis is the quantity of memory cells, PPV is the verification voltage configured for a pre-programming verification, and EV, EV1, and EV2 are verification voltages configured for the erase verification. The verification voltage EV2 (a second verification voltage) is greater than the verification voltage EV1 (a first verification voltage). The verification voltage EV1 is greater than the verification voltage EV.

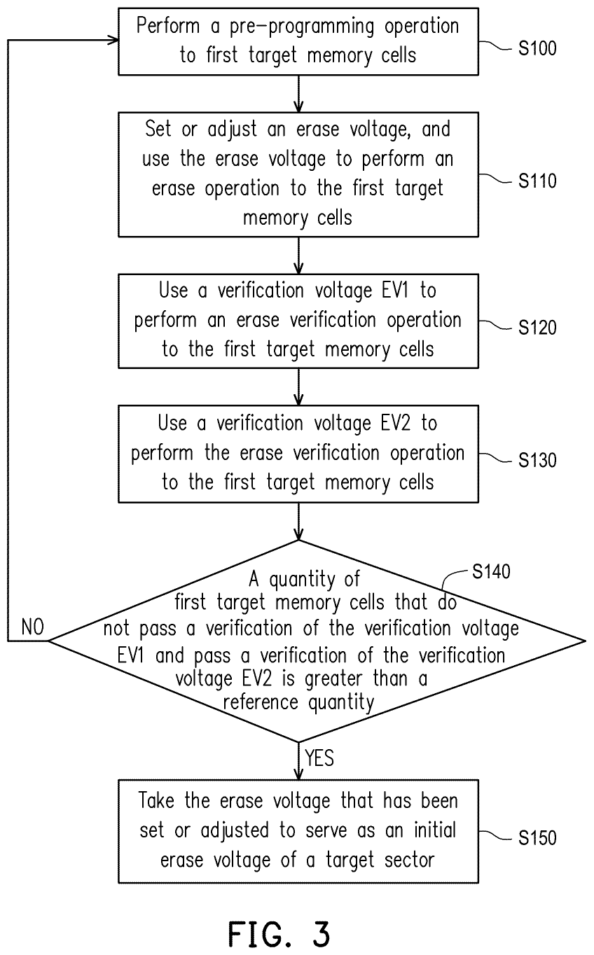

In the embodiment, the control circuit 150 may, for example, use the method flow in FIG. 3 to set the initial erase voltage for each sector. The initial erase voltage of each sector may be set to be the same or different. Generally, in a block erase command, the initial erase voltages of all sectors are the same. The algorithm of the embodiment of the disclosure may find the erase voltage that has been adjusted and apply on all sectors of the erased block at the same time. If the erase command is a sector erase command, the algorithm of the embodiment of the disclosure may find the erase voltage that has been adjusted and apply on the sector. In FIG. 2, a distribution curve 200 is a distribution of threshold voltages of memory cells of an entire target sector after the pre-programming operation is performed to the selected sector (hereinafter referred to as the target sector).

In step S100, the control circuit 150 selects first target memory cells from the target sector to perform the pre-programming operation. In an embodiment, a quantity of the first target memory cells is, for example, 32, 64, 128, or other appropriate quantities. The disclosure does not limit the quantity of the first target memory cells. In step S100, the control circuit 150 may also perform the pre-programming operation to the entire target sector.

In the sense amplifier circuit 120, a corresponding quantity of sense amplifiers 122 may perform a sensing operation to the first target memory cells to complete the erase verification operation. The voltage generating circuit 130 may provide the verification voltages EV, EV1, and EV2 to the sense amplifier 122 through a same signal line L1.

In step S110, the control circuit 150 sets a first erase voltage and uses the first erase voltage that has been set to perform the erase operation to the first target memory cells. In step S120, the control circuit 150 uses the verification voltage EV1 to perform the erase verification operation to the first target memory cells. Next, in step S130, the control circuit 150 uses the verification voltage EV2 to perform the erase verification operation to the first target memory cells. That is to say, in the embodiment, the control circuit 150 uses the verification voltages EV1 and EV2 to sequentially perform the erase verification operation to the first target memory cells.

In step S140, the control circuit 150 may determine whether the quantity of first target memory cells that do not pass a verification of the verification voltage EV1 and pass a verification of the verification voltage EV2 is greater than a reference quantity.

When the quantity of the first target memory cells that do not pass the verification of the verification voltage EV1 and pass the verification of the verification voltage EV2 is greater than the reference quantity, it means that the first erase voltage that has been set in step S110 by the control circuit 150 is appropriate to serve as the initial erase voltage. Therefore, in step S150, the control circuit 150 sets the first erase voltage as the initial erase voltage of the target sector. In the embodiment, the reference quantity may be preset, and the reference quantity may also be a reference proportion.

On the other hand, when the quantity of the first target memory cells that pass the verification of the verification voltage EV1 is greater than or equal to the reference quantity (such as a distribution curve 210 in FIG. 2), it means that the first erase voltage is too high. The control circuit 150 may return to step S100 and perform the pre-programming operation to the first target memory cells again. In step S110, the control circuit 150 decreases the first erase voltage as a second erase voltage and uses the second erase voltage to perform the erase operation to the target memory cells. Next, in steps S120 and S130, the control circuit 150 uses the verification voltages EV1 and EV2 to sequentially perform the erase verification operation to the first target memory cells. In step S140, if the second erase voltage may allow the quantity of first target memory cells that do not pass the verification of the verification voltage EV1 and pass the verification of the verification voltage EV2 to be greater than the reference quantity, in step S150, the control circuit 150 sets the second erase voltage as the initial erase voltage of the target sector.

Alternatively, when the quantity of the first target memory cells that do not pass the verification of the verification voltage EV2 is greater than or equal to the reference quantity (such as a distribution curve 220 in FIG. 2), it means that the first erase voltage is too low. The control circuit 150 may return to step S100 and perform the pre-programming operation to the first target memory cells again. In step S110, the control circuit 150 increases the first erase voltage as a third erase voltage and uses the third erase voltage to perform the erase operation to the target memory cells. Next, in steps S120 and S130, the control circuit 150 uses the verification voltages EV1 and EV2 to sequentially perform the erase verification operation to the first target memory cells. In step S140, if the third erase voltage may allow the quantity of first target memory cells that do not pass the verification of the verification voltage EV1 and pass the verification of the verification voltage EV2 to be greater than the reference quantity, in step S150, the control circuit 150 sets the third erase voltage as the initial erase voltage of the target sector.

In the embodiment of FIG. 1, the counter circuit 140 includes a first counter circuit 142 and a second counter circuit 144. The first counter circuit 142 is configured to count the quantity of the first target memory cells that pass the verification of the verification voltage EV1 and provide a counting result to the control circuit 150. The second counter circuit 144 is configured to count the quantity of the first target memory cells that do not pass the verification of the verification voltage EV2 and provide a counting result to the control circuit 150.

In the embodiment of FIG. 3, the control circuit 150 may repeatedly execute step S100 to step S140 until “yes” is determined in step S140, and then the control circuit 150 executes step S150, but the disclosure is not limited thereto. In another embodiment, as long as a predetermined number of times of the erase operation (such as twice) are performed to the first target memory cells, the control circuit 150 may execute step S150 and take the erase voltage that has been adjusted to serve as the initial erase voltage of the target sector.

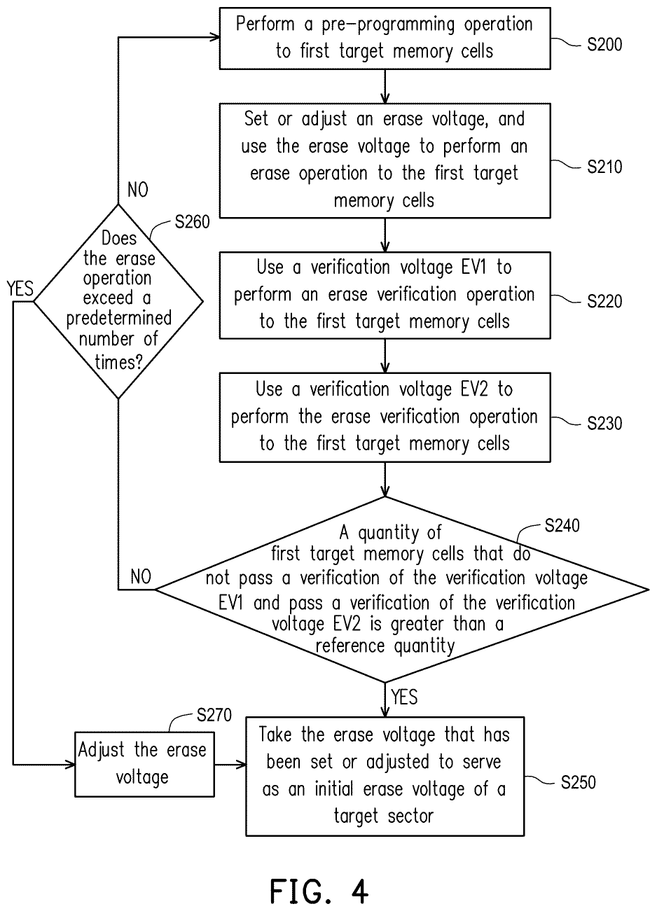

Specifically, refer to FIG. 4. In the embodiment of FIG. 4, the control circuit 150 repeatedly execute step S200 to step S240, and after the predetermined number of times of the erase operation are performed to the first target memory cells, step S250 is executed. That is to say, in step S260, the control circuit 150 may determine whether the erase operation performed to the first target memory cells exceeds the predetermined number of times. When the erase count exceeds the predetermined number of times, the control circuit 150 may execute step S250 after the erase voltage is adjusted in step S270 to take the erase voltage that has been adjusted to serve as the initial erase voltage of the target sector. In the embodiment, the predetermined number of times is, for example, twice, but the disclosure is not limited thereto.

Therefore, the initial erase voltage needed for the erase operation may be set for each sector through the method in FIG. 3 or FIG. 4. In addition, the same or different initial erase voltages may also be set for each block through the method in FIG. 3 or FIG. 4.

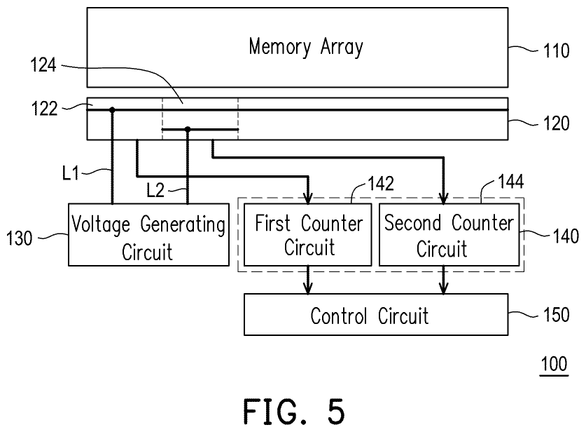

Refer to FIG. 1 and FIG. 5. In the embodiment of FIG. 1, the control circuit 150 uses the verification voltages EV1 and EV2 to sequentially perform the erase verification operation to the first target memory cells. Furthermore, the voltage generating circuit 130 provides the verification voltages EV, EV1, and EV2 to the sense amplifier 124 through the same signal line L1, but the disclosure is not limited thereto.

In the embodiment of FIG. 5, the control circuit 150 may use the verification voltage EV1 to perform the erase verification operation to the first target memory cells and use the verification voltage EV2 to perform the erase verification operation to second target memory cells at the same time, which may save time for the erase verification. The first target memory cells and the second target memory cells are different groups of target memory cells in the same block or sector. The quantity of the second target memory cells is the same as the quantity of the first target memory cells. Therefore, in the embodiment, the control circuit 150 uses the verification voltages EV1 and EV2 to respectively perform the erase verification operation to the first target memory cells and the second target memory cells to set the initial erase voltage based on verification results of the two.

The voltage generating circuit 130 provides the verification voltages EV and EV1 to the sense amplifier 122 corresponding to the first target memory cells through the signal line L1. The voltage generating circuit 130 provides the verification voltage EV2 to the sense amplifier 124 corresponding to the second target memory cells through a signal line L2.

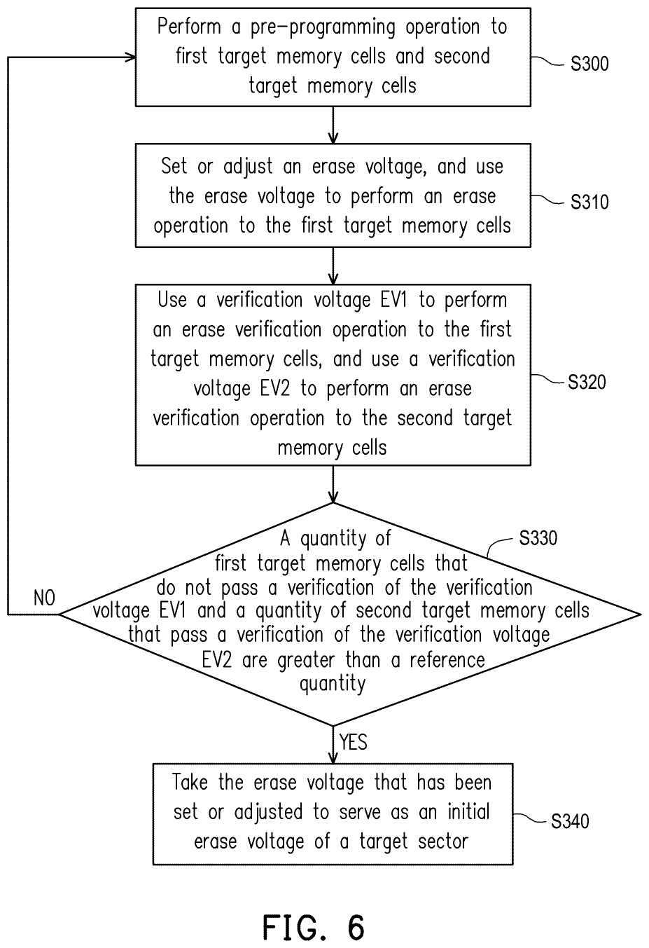

Refer to FIG. 6. In the embodiment, in step S320, the control circuit 150 uses the verification voltage EV1 to perform the erase verification operation to the first target memory cells, and uses the verification voltage EV2 to perform the erase verification operation to the second target memory cells at the same time. Next, in step S330, the control circuit 150 may determine whether the quantity of first target memory cells that do not pass the verification of the verification voltage EV1 and the quantity of second target memory cells that pass the verification of the verification voltage EV2 are greater than the reference quantity. Therefore, in step S340, the control circuit 150 may take the erase voltage that is set or adjusted to serve as the initial erase voltage of the target sector.

Therefore, in the embodiment of FIG. 6, the verification voltages EV1 and EV2 are used to respectively perform the erase verification operation to the first target memory cells and the second target memory cells to set the initial erase voltage based on the verification results of the two.

In the embodiment of FIG. 6, the control circuit 150 may also repeatedly execute step S300 to step S330, and after the predetermined number of times of the erase operation are performed to the first target memory cells and the second target memory cells, step S340 is executed. That is, when the erase count exceeds the predetermined number of times, the control circuit 150 may execute step S340 after the erase voltage is adjusted to take the erase voltage that has been adjusted to serve as the initial erase voltage of the target sector.

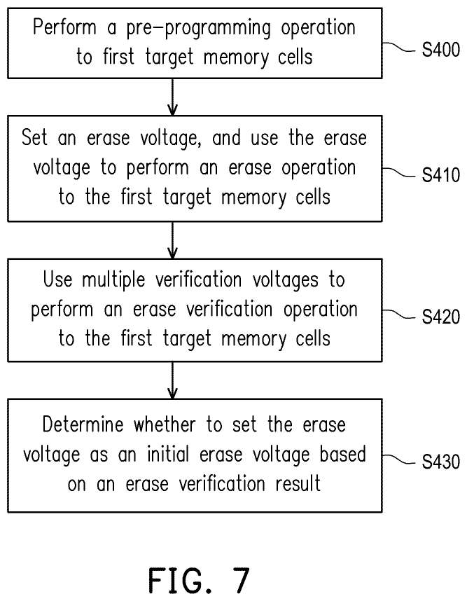

Refer to FIG. 1 and FIG. 7. A method of setting an initial erase voltage of the embodiment is applicable to the memory storage device 100 in FIG. 1, but the disclosure is not limited thereto. Taking the memory storage device 100 in FIG. 1 as an example, in step S400, the control circuit 150 performs the pre-programming operation to the first target memory cells. In step S410, the control circuit 150 sets the erase voltage and uses the erase voltage to perform the erase operation to the first target memory cells. In step S420, the control circuit 150 uses the multiple verification voltages EV1 and EV2 to perform the erase verification operation to the first target memory cells. In step S430, the control circuit 150 determines whether the erase voltage is set as the initial erase voltage based on an erase verification result.

In addition, the method of setting the initial erase voltage in the embodiment can obtain sufficient teachings, suggestions and implementation instructions from the description of the embodiments in FIG. 1 to FIG. 6, and therefore will not be described again.

In summary, in the embodiment of the disclosure, through using multiple verification voltages to perform multiple erase verification operations to one or multiple target memory cells of the same block or sector, the initial erase voltage appropriate for the block or the sector may be determined. Therefore, through the method of setting the initial erase voltage according to the embodiment of the disclosure, different initial erase voltages may be set for memory dies to reduce an erase time. In addition, before each cycling operation begins, the control circuit may also reset the initial erase voltage for the erase operation.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A method for setting an initial erase voltage, comprising:
performing a pre-programming operation to first target memory cells;
performing an erase operation to the first target memory cells by setting an erase voltage and using the erase voltage;
performing an erase verification operation to the first target memory cells by using a plurality of verification voltages wherein the plurality of verification voltages comprise a first verification voltage and a second verification voltage, and the second verification voltage is greater than the first verification voltage, and steps of performing the erase verification operation to the first target memory cells by using the plurality of verification voltages comprise performing the erase verification operation to the first target memory cells by sequentially using the first verification voltage and the second verification voltage; and
determining whether to set the erase voltage as the initial erase voltage based on an erase verification result, wherein steps of determining whether to set the erase voltage as the initial erase voltage based on the erase verification result comprise:
setting the erase voltage as the initial erase voltage when a quantity of first target memory cells that do not pass a verification of the first verification voltage and pass a verification of the second verification voltage is greater than a reference quantity.

2. The method according to claim 1, wherein steps of performing the pre-programming operation to the first target memory cells comprise:
performing the pre-programming operation to a block or a sector where the first target memory cells are located.

3. The method according to claim 1, wherein steps of determining whether to set the erase voltage as the initial erase voltage based on the erase verification result comprise:
adjusting the erase voltage when a quantity of first target memory cells that pass a verification of the first verification voltage is greater than or equal to a reference quantity, or when a quantity of first target memory cells that do not pass a verification of the second verification voltage is greater than or equal to the reference quantity.

4. The method according to claim 3, further comprising:
performing the erase operation to the first target memory cells by using the erase voltage that has been adjusted, wherein the steps of determining whether to set the erase voltage as the initial erase voltage based on the erase verification result comprise:
setting the erase voltage that has been adjusted as the initial erase voltage based on the erase verification result.

5. The method according to claim 3, wherein the steps of determining whether to set the erase voltage as the initial erase voltage based on the erase verification result comprise:
decreasing the erase voltage to set the erase voltage that has been decreased as the initial erase voltage when the quantity of the first target memory cells that pass the verification of the first verification voltage is greater than or equal to the reference quantity.

6. The method according to claim 3, wherein the steps of determining whether to set the erase voltage as the initial erase voltage based on the erase verification result comprise:
increasing the erase voltage to set the erase voltage that has been increased as the initial erase voltage when the quantity of the first target memory cells that do not pass the verification of the second verification voltage is greater than or equal to the reference quantity.

7. The method according to claim 1, further comprising:
performing a pre-programming operation to second target memory cells;
performing an erase operation to the second target memory cells by using the erase voltage; and
performing the erase verification operation to the second memory target cells by using the plurality of verification voltages, wherein the first target memory cells and the second target memory cells are different groups of target memory cells in a same block or sector.

8. The method according to claim 7, wherein the erase verification operations of the first target memory cells and the second target memory cells are performed at the same time.

9. The method according to claim 7,
wherein the plurality of verification voltages comprise a first verification voltage and a second verification voltage, and the second verification voltage is greater than the first verification voltage,
wherein steps of performing the erase verification operation to the first target memory cells by using the plurality of verification voltages comprise performing the erase verification operation to the first target memory cells by using the first verification voltage,
wherein steps of performing the erase verification operation to the second target memory cells by using the plurality of verification voltages comprise performing the erase verification operation to the second target memory cells by using the second verification voltage.

10. The method according to claim 7, wherein a number of the erase operation performed to the first target memory cells or the second target memory cells is less than or equal to a predetermined number of times.
